(19) United States
(12) Patent Application Publication
(10) Pub. No.: US 2008/0018396 A1
(43) Pub. Date: Jan. 24, 2008

(54) WIDEBAND HYPERFREQUENCY DETECTION DEVICE

(75) Inventors: Benoit MALLET-GUY, Paris (FR); Philippe Dueme, Orsay (FR)

Correspondence Address: LOWE HAUPTMAN & BERNER, LLP, 1700 DIAGONAL ROAD, SUITE 300, ALEXANDRIA, VA, 22314, US

(73) Assignee: THALES, NEUILLY SUR SEINE (FR)

(21) Appl. No.: 11/767,392

(22) Filed: Jun. 22, 2007

(30) Foreign Application Priority Data
Jun. 23, 2006 (FR) 0605661

(51) Int. Cl. H03F 3/60

(52) U.S. Cl. 330/54

(57) ABSTRACT

The present invention relates to a hyperfrequency detection module. It also relates to a wideband hyperfrequency detection device comprising one or more detection modules. The detection module comprises includes: a distributed amplifier (50) having N field-effect transistors (55), and a common drain line (56), a common gate line (54). The distributed amplifier has an input (52) on its common gate line (54) and an output (53) on the common drain line (56). A semiconductor-based detection circuit (51) and the detection circuit (51) are connected to one end (59) of the gate line (54) of the distributed amplifier (50). The invention applies in particular to the production of hyperfrequency monolithic circuit detectors.

### RELATED APPLICATIONS

The present application is based on, and claims priority from, French Application Number 06 05661, filed Jun. 23, 2006, the disclosure of which is hereby incorporated by reference herein in its entirety.

### BACKGROUND OF THE INVENTION

The present invention relates to a hyperfrequency detection module. It also relates to a wideband hyperfrequency detection device comprising one or more detection modules. It applies in particular to the production of hyperfrequency monolithic circuit detectors.

### DESCRIPTION OR PRIOR ART

A power level detector is used in order to know instantaneously the power level of a received hyperfrequency signal. The main characteristics sought for a wideband power level detector are in particular that it should operate over a wide frequency band, that it can measure a signal over a wide dynamic range of power levels and that it has a good sensitivity to low received signal power levels.

To this end, one known architecture consists in cascading a unitary circuit consisting of three components: a diode, a power divider and a wideband amplifier. In this case, the wideband amplifier used can be a hyperfrequency integrated circuit of the microwave monolithic integrated circuit (MMIC) type, having a so-called distributed architecture. The power divider used in the unitary circuit can be a Wilkinson-type structure which makes it possible to process a wide frequency-band signal. The drawbacks of this unitary circuit are mainly linked to the presence of the Wilkinson-type divider. Said divider introduces in particular a high noise figure into the processed signal. The sensitivity of the diode for minimum amplitudes is thus reduced by the losses due to the Wilkinson-type divider. Independently of the divider, the unitary circuit has the drawback of being made up of three separate components that must be wired to each other and that are derived from potentially different technologies. Furthermore, the divider used to process a hyperfrequency signal needs to process a wide frequency band. A wideband Wilkinson-type divider presents numerous production difficulties and in particular difficulties of integration in an electronic system. The resultant circuit is large and generates considerable internal losses because of the difficulties linked to the adaptation of this type of assembly. This induces a high production cost associated with the complexity in producing such a circuit.

### SUMMARY OF THE INVENTION

One aim of the invention is in particular to overcome the abovementioned drawbacks. To this end, the subject of the invention is a hyperfrequency detection module comprising:
a distributed amplifier comprising N field-effect transistors connected to a common drain line and to a common gate line, the distributed amplifier having an input on the common gate line and an output on the common drain line,
a semiconductor-based detection circuit, the detection circuit being connected to one end of the gate line of the distributed amplifier. The detection circuit can, for example, be a Schottky diode or a PN diode.

The module can, moreover, comprise a distributed amplifier having a gate line common with said detection module. The module then divides the signal, received on an input of the common gate line, into two signals, one being directed to the output of the detection module and the second to an output of the distributed amplifier. The module can also switch the signal, received on the input of the common gate line, either to the output of the detection module, or to an output of the distributed amplifier, the switching being performed by a bias voltage-mode control of the transistors of the detection module and of the distributed amplifier.

The module can also comprise a second detection module comprising:
a distributed amplifier comprising N field-effect transistors connected to a common drain line and to a common gate line, the distributed amplifier having an input on the common gate line and an output on the common drain line,
a semiconductor-based detection circuit, the detection circuit being connected to one end of the gate line of the distributed amplifier, and sharing the drain line common with said detection module. The module switches the signal, received on one of the inputs, to the output of the drain line common to the two detection modules, the switching being performed by a bias voltage-mode control of the transistors.

An impedance can be connected in series to the detection circuit to match this circuit to the characteristic impedance of the gate line of the detection module.

Another subject of the invention is a detection device, which comprises P detection modules, linked in cascade fashion, an output of a module being linked to an input of the next module.

The main advantage of the invention is that it covers a wide dynamic range of power levels while having a good sensitivity to low power levels. Furthermore, the detector circuit according to the invention has the advantage of being modular, which enables it to be used in multiple configurations and applications. The device according to the invention also has the advantage of being simple to implement and offering a certain flexibility of production. It can also have a small size depending on the production methods employed.

### BRIEF DESCRIPTION OF THE DRAWINGS

Other characteristics and advantages of the invention will become apparent from the description that follows in light of the appended drawings which represent:

FIG. 1a: the diagram of a diode;

FIG. 1b: a voltage delivered at the terminals of a diode according to the power of the current passing through it;

FIG. 2a: the theoretical diagram of a detection circuit comprising two diodes;

FIG. 2b: the voltage-power mode operation of two detector diodes;

FIG. 3: an architecture of a wideband level and wide dynamic range detector circuit according to the prior art;

FIG. 4: a theoretical diagram of a distributed amplifier;

FIG. 5: a diagram of an active wideband detector circuit according to the invention;

FIGS. 6 and 7: variants of possible embodiments of the detector according to the invention.

### DETAILED DESCRIPTION OF A PREFERRED EMBODIMENT

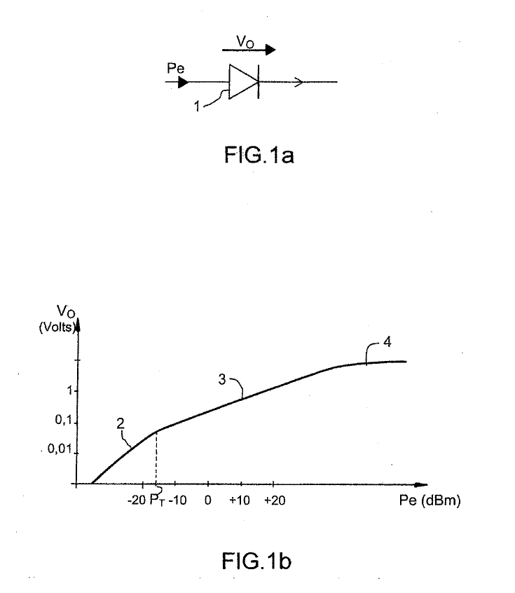

FIG. 1a diagrammatically shows a semiconductor-based detector 1 used in the context of the invention in order to detect the power of the received signal. This detector can, for example, be a PN diode or a Schottky diode. FIG. 1b represents the voltage-power characteristic of the diode 1. This diode 1 is therefore used in order to detect the electrical power Pₑ of a signal passing through it. One characteristic of the diode 1 is that it delivers at its terminals a DC voltage V₀, the amplitude of which is a quadratic function 2 of the power level Pₑ passing through it. The detection-mode operating area 2 of the diode 1 is located for power levels less than a power P_{T}. Above this power, the diode 1 switches to a linear regime 3 during which its detection capabilities cannot be used, then, when the received power Pₑ increases further, the diode 1 switches to a saturation state 4.

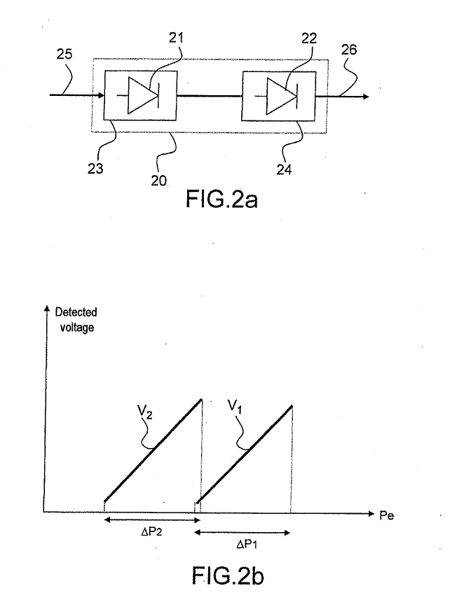

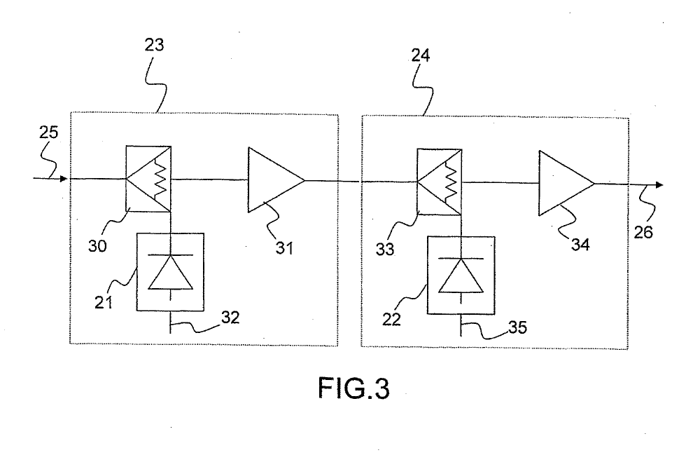

FIG. 2a represents the theoretical diagram of a detection system 20 using several detection circuits. This system 20 is, for example, made up of two circuits 23, 24, each comprising a detector diode 21, 22, for example of the type of the diode presented in FIG. 1a. These two circuits 23, 24 are cascaded, the hyperfrequency signal driving the circuit 23 via an input 25. The diode 21 detects a voltage V₁ then the signal leaves the circuit 23 to enter into the circuit 24 where the diode 22 detects a voltage V₂. The signal leaves the detection circuit 20 at an output point 26. The advantage of using in series at least two circuits 23, 24, each comprising a detector diode 21, 22, is to be able to process a wider range of frequencies, subject to amplifying the signal from one circuit to the other as will be described in relation to FIG. 3.

FIG. 2b shows the operation of the voltage-power mode detection of several diodes linked in series. The detection principle using a diode is to use its detection area 2 shown in the diagram 1b in order to detect a voltage at its terminals that is a function of the power Pₑ of the received signal. This detection area 2 corresponds to a defined power range, the values of which depend on the characteristics of the diode used. In order to widen the range of powers over which detection takes place, two diodes 21 and 22, like that described in the diagram 2a, can, for example, be used. The circuit 23 receives at the input a hyperfrequency signal of power Pₑ. The diode 21 detects a voltage V₁ for powers Pₑ within a range ΔP₁. Then, the signal leaving the circuit 23 is amplified. It then enters into the circuit 24 in which the diode 22 detects a voltage V₂ for powers Pₑ, within a range ΔP₂, that are lower overall. The amplification of the signal makes it possible for the power received by the circuit 24 to be within the power range corresponding to the detection area 2 of the diode 22. By amplifying the signal, it therefore becomes possible to use the diodes so that their detection areas 2 complement each other in order to cover a sufficiently wide range of received powers Pₑ.

FIG. 3 shows an example of a wideband power level detector circuit according to the prior art. In order to measure the signal over a wide dynamic range of power levels and over a wide frequency band, one architecture that is frequently used consists in cascading a unitary circuit 23 as described in FIG. 2a. This unitary circuit 23 can, for example, comprise three components: a detector diode 21 as described in FIGS. 1a and 1b for example, a power divider 30, and a wideband amplifier 31. The wideband amplifier 31 can, for example, be a hyperfrequency integrated circuit having a distributed architecture.

A hyperfrequency signal enters at an access point 25 of the first of the unitary circuits 23, the figure representing for the example two unitary circuits 23, 24. The power of the received signal is then divided by the power divider 30. One part of the power leaves into the detector diode 21 which consumes this power and supplies at the output 32 a detected voltage V₁. The second part of the signal enters into the wideband amplifier 31 in order to be amplified. This first unitary circuit 23 makes it possible, for example, to detect high power signal levels as described in FIG. 2b. The signal leaving the amplifier 31 drives the input of the second unitary circuit 24. It first passes through a power divider 33 which directs, for example, a first half of the power of the signal to a detector diode 22 and a second half to a wideband amplifier 34. The wideband amplifier 34 reamplifies the signal before delivering it either to the output 26 of the circuit or to the input of another unitary circuit, not shown, in order to detect a third power level. The diode 22 delivers at its terminals a voltage V₂ dependent on the power entering the latter as described in the diagram 2b. The second circuit 24 is therefore used to detect a power level of the signal that is lower than the first power level detected by the first unitary circuit 23. The outputs 32, 35 of each diode 21, 22 have connected to them electronic circuits known elsewhere and not represented for measuring the voltage at the terminals of the diode.

Such a circuit has numerous drawbacks, including production difficulties and difficulties of integration into an electronic system. The result is that systems made in this way are of large size and therefore costly. The size of these systems also generates significant internal losses, which reduces the sensitivity of the detection circuit.

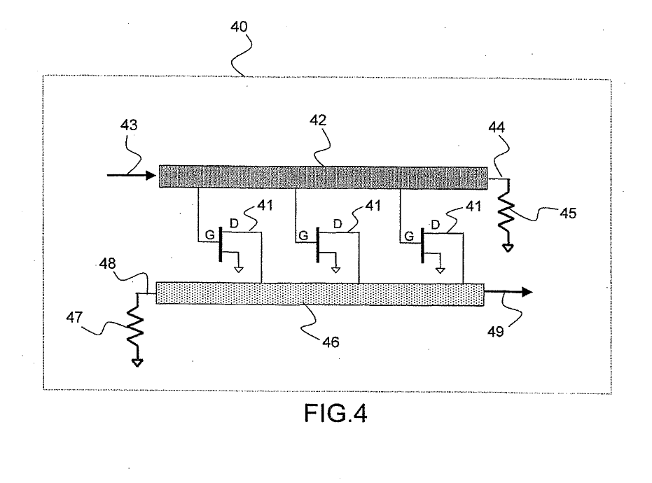

FIG. 4 represents a theoretical diagram of a distributed amplifier 40 used in a detector according to the prior art. This distributed amplifier 40 comprises N amplifying cells mounted in parallel, based on one or more field-effect transistors. In the example of FIG. 4, each amplifying cell comprises a transistor 41. The gate of a transistor is linked to a common gate line 42 which extends from an input point of the assembly 43 to an access point 44 to which is connected a resistor 45 linked to a reference potential. The drain of the transistor is linked to a common drain line 46 which extends between a resistor 47, mounted on an access 48 of the drain line 46 and linked to a reference potential, and an output point 49 of the assembly. The source of the transistor is linked to the reference potential. Consequently, the reference potential will be comparable to the electrical zero or to the mechanical ground.

The gate 42 and drain 46 lines are lines mainly consisting of capacitors internal to the transistors 41 and of inductors possibly linked by mutual inductors. These adapted inductors are in particular provided to match the line to a characteristic impedance, for example of 50 ohms. In order to match the line, the resistor 45 forming an ancillary load is thus provided at 50 ohms. The input of the common gate line 42 forms the input 43 of the distributed amplifier 40. The other end 44 of the gate line is loaded on a terminal resistor or ancillary load 45, the resistance value of which is roughly equal to the characteristic impedance of the common gate line 42.

In the case of an MMIC-technology implementation, the connections of the ancillary loads are normally made on the chip and the accesses 44, 48 are not available.

As on the gate line 42, one end of the common drain line 46 is loaded on a terminal resistor 47, the resistance value of which is roughly equal to the characteristic impedance of the common drain line 46, whereas the other end of the common drain line 46 defines the output 49 of the distributed amplifier. A bias circuit, not shown in FIG. 4, applies a DC bias voltage to the common gate line 42.

The operation of a distributed amplifier of the type illustrated in FIG. 4 is as follows. A hyperfrequency signal received at the input 43 is propagated over the common gate line 42 to be absorbed by the ancillary load 45. Over each gate of transistors 41 a signal therefore passes, being propagated from the input 43 to the ancillary load 45. This signal is propagated through the transistors 41 to the output 49, the other end 48 of the drain line 46 being loaded by its characteristic impedance. This hyperfrequency signal being amplified by the transistors 41, the amplification is of very wideband width because it extends from DC to the cut-off frequencies linked to the characteristics of the transistors 41. These cut-off frequencies can be very high, from several tens of GHz to a hundred or so GHz.

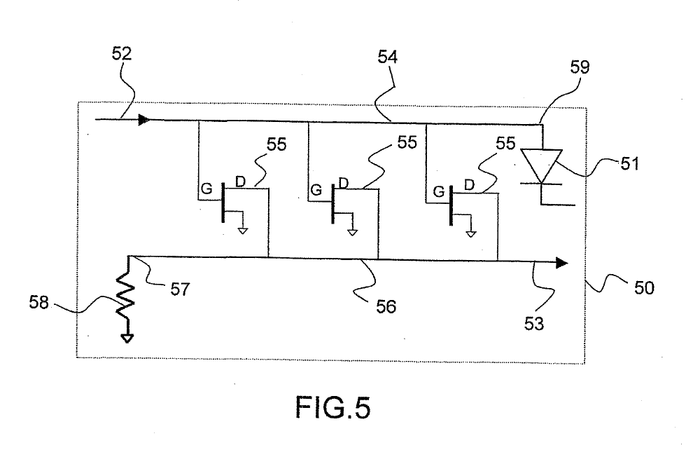

FIG. 5 represents a basic module 50 used in a detection device according to the invention. This basic module is a circuit incorporating a distributed amplifier as described in FIG. 4, the ancillary load 45 being replaced by a detection circuit, a diode 51 for example. The basic circuit of the detector according to the invention therefore consists of an input 52, an amplified output 53, N transistors 55, a common gate line 54, a common drain line 56, an access 57 to the drain line 56 to which is connected an ancillary load 58 and an access 59 to the gate line 54. This access 59 of the detector circuit can be left free. This therefore makes it possible to connect the semiconductor-based detection circuit like, for example, a diode 51, as described in figures la and lb. This diode 51 thus makes it possible for the access 59 to behave as an unamplified ancillary output on which the power level of the received signal is detected via the diode 51. The level of the voltage at the terminals of the diode, dependent on the power level of the received signal, is then measured by a matched circuit, not shown in the figure. The power level of the measured signal is little attenuated relative to the input signal. An impedance is, for example, linked in series to the diode 51 to match the diode to the characteristic impedance of the gate line 54. Advantageously, the diode 51 can be internal or external to an integrated circuit comprising the amplifier.

The embodiment of this circuit is, for example, the same as that of the distributed amplifier, that is, an MMIC technology.

The detection module 50 according to the invention can be used in cascade mode in place of the unitary circuits 23, 24 used in the assembly described in FIG. 2a, by linking, for example, the output 53 of the first module 23 to the input 52 of the second module 24. This makes it possible to construct a wideband active detector for a wide dynamic range of power levels, each of the circuits 23, 24 detecting a given power range.

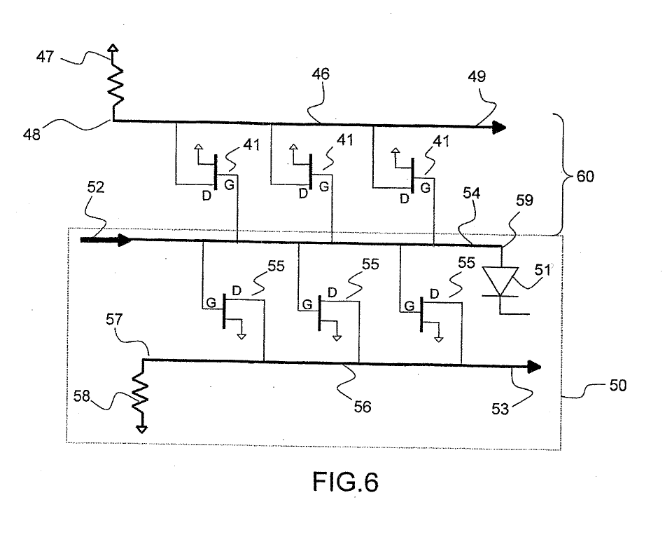

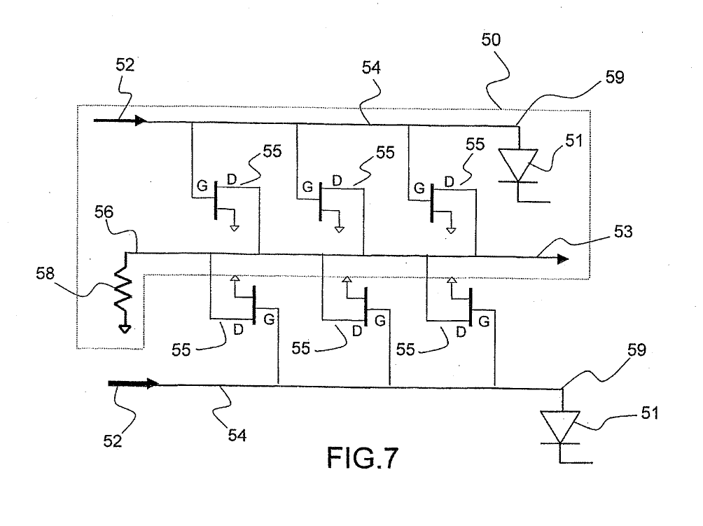

FIGS. 6 and 7 represent two of the variants of use of the detection module according to the invention.

A first variant represented in FIG. 6 is a detection circuit having two amplified outputs. This circuit consists of a detection module 50 according to the invention, the gate line 54 of which is common with a distributed amplifier 60 like that described in FIG. 4. The distributed amplifier 60 therefore has a gate line 54 common with the detection module 50. The gates of the N transistors 41 of the distributed amplifier 60 are therefore connected to the common gate line 54 by their gate, their drain being connected to a common drain line 46. The drain line 46 has at one end 48 an ancillary load 47 according to the principle of the distributed amplifier represented in FIG. 4.

The second end 49 of the drain line 46 offers a second output to the detection and amplification circuit. This assembly enables the circuit to supply two different amplified outputs 49 and 53, while retaining an output having a means 51 of detecting the power level of the signal in order to be able to measure the power level of the signal entering the circuit assembly at the input point 52. This circuit can be used for example as a detector circuit having two outputs, one part of the signal being able to be directed to the output 49 and the second part of the signal being able to be directed to the output 53. In another embodiment, this circuit can also be used as a detector circuit and switch. The switching can be used to direct the signal received on the input 52 to the output 53 or the output 49 by acting on the bias of the transistors. For example, applying a bias voltage-mode control to the first series of transistors 41 makes it possible to make the latter conductive and another bias voltage-mode control applied to the other series of transistors 55 can be used to render the latter nonconductive. The signal received on the input 52 is then directed to the output 49 of the detection circuit.

FIG. 7 shows a second variant: a circuit with two detection inputs. This circuit can be produced by taking a double detection module 50 according to the invention. The two modules have a common drain line 56, the second module being symmetrical to the first module 50 relative to the common drain line 56. This drain line 56 common to the two modules has a set of N transistors 55 connected via their drain. The gate of each of the transistors 55 is connected to a common gate line 54. The gate line 54 has an input 52 for a hyperfrequency signal. The signal received on the input 52 can be detected at the access 59 by a detector diode 51 as described by FIGS. 1a and 1b for example. The circuit assembly then has two inputs 52 thus making it possible to obtain a double detection and combine the two received signals into an amplified signal leaving on the access 53.

In another embodiment, it is also possible to switch one or other of the received signals to the output 53 by acting on the bias of the transistors, each of the received signals being detected by the diodes 51 then measured by an appropriate circuit not represented in FIG. 7. The transistors 55 of the module 50 can, for example, be controlled in bias voltage mode in order to render them conductive, the transistors of the second module then being controlled in bias voltage mode in order to render them nonconductive. The signal received on the input 52 of the first module 50 is then directed to the output 53 of the double detection module.

The two FIGS. 6 and 7 illustrate two examples of the modularity of the detection module according to the invention. This detection module can thus be used or adapted in different types of assemblies for various uses.

A wideband power level detection module 50 according to the invention has the advantage of being able to be combined, for example, with other amplifier circuits or other wideband level detection modules 50 in multiple configurations that can be adapted to each specific need in terms of detection of the power level of a signal and its amplification for example.

A wideband power level detection module 50 can be produced in accordance with MMIC technology. The simplicity of such a module advantageously makes it possible to produce an MMIC circuit of small size and of much simpler design than a circuit according to the prior art, hence a saving in space and in production cost.

Another advantage of the detection module 50 is its great flexibility of implementation. In practice, it is possible to leave out the diode 51 of the circuit 50, thus leaving its access point 59 free to connect an appropriate diode externally.

A wideband active detector circuit for a wide dynamic frequency range can be obtained by cascading the detection module 50. This assembly makes it possible advantageously to obtain a good detection sensitivity for different power levels of the received signal, and in particular for low power levels.

1. A hyperfrequency detection module, comprising:
a distributed amplifier having N field-effect transistors connected to a common drain line and to a common gate line, the distributed amplifier having an input on the common gate line and an output on the common drain line,
a semiconductor-based detection circuit, being connected to an end of the gate line of the distributed amplifier.

2. The module as claimed in claim 1, wherein the detection circuit is a diode.

3. The module as claimed in claim 2, wherein the diode is a Schoftky diode.

4. The module as claimed in claim 2, wherein the diode is a PN diode.

5. The module as claimed in claim 1, comprising a distributed amplifier having a gate line common with said detection module.

6. The module as claimed in claim 5, wherein the signal received is divided on an input of the common gate line, into two signals, one being directed to the output of the detection module and the second to an output of the distributed amplifier.

7. The module as claimed in claim 5, wherein the signal received is switched on the input of the common gate line, either to the output of the detection module, or to an output of the distributed amplifier, the switching being performed by a bias voltage-mode control of the transistors of the detection module and of the distributed amplifier.

8. The module as claimed in claim 1, further comprising a second detection module including:
a distributed amplifier comprising N field-effect transistors connected to a common drain line and to a common gate line, the distributed amplifier having an input on the common gate line and an output on the common drain line,
a semiconductor-based detection circuit, the detection circuit being connected to one end of the gate line of the distributed amplifier, and sharing the common drain line with said detection module.

9. The module as claimed in claim 8, wherein the signal received on one of the inputs is switched, to the output of the drain line common to the two detection modules, the switching being performed by a bias voltage-mode control of the transistors.

10. The module as claimed in claim 1, wherein an impedance is connected in series to the detection circuit to match this circuit to the characteristic impedance of the gate line of the detection module.

11. A detection device, comprising P detection modules as claimed in claim 1, linked in cascade fashion, an output of a module being linked to an input of the next module.
